(19) United States
(12) Patent Application Publication
(10) Pub. No.: US 2025/0029905 A1
(43) Pub. Date: Jan. 23, 2025

(54) STRUCTURE OF CHIP PACKAGE INTEGRATED ANTENNA AND MANUFACTURING METHOD THEREOF

(71) Applicant: Universal Global Technology (Shanghai) CO., Ltd., Shanghai (CN)

(72) Inventors: HONGSONG YU, Shanghai (CN); BIAO HU, Shanghai (CN); YANBIN PENG, Shanghai (CN)

(21) Appl. No.: 18/470,409

(22) Filed: Sep. 19, 2023

(30) Foreign Application Priority Data
Jul. 19, 2023 (CN) 202310892117.4

(51) Int. Cl. H01L 23/498; H01L 21/56; H01L 23/31; H01Q 1/22

(52) U.S. Cl. CPC H01L 23/49811; H01L 21/56; H01L 23/3121; H01Q 1/2283

(57) ABSTRACT

A structure of a chip package integrated antenna and a manufacturing method thereof are proposed, and the structure includes a substrate, at least one chip unit, at least two conductive units, an encapsulation, at least two conductive structures and an antenna. The chip unit and the two conductive units are disposed on the substrate. The encapsulation covers the chip unit and the two conductive units, and has a top surface and at least two through holes. The two through holes are respectively formed between the top surface and the two conductive units. The two conductive structures are respectively disposed on the two conductive units and located in the two through holes. The antenna is disposed on the top surface and connected to the two conductive structures, and is electrically connected to the chip unit through the two conductive structures, the two conductive units and the substrate in sequence.

### RELATED APPLICATIONS

This application claims priority to China Patent Application Serial Number 202310892117.4, filed Jul. 19, 2023, which is herein incorporated by reference.

### BACKGROUND

### Technical Field

The present disclosure relates to an integrated circuit packaging technology field. More particularly, the present disclosure relates to a structure of a chip package integrated antenna and a manufacturing method thereof.

### Description of Related Art

With the rise of System in Package (SiP) technology, the system integration of the chip is getting higher and higher. In the current SiP module, although most of the circuits have been integrated, the antenna often needs to be assembled separately. In order to assemble the antenna, it is usually necessary to transfer through a Printed Circuit Board (PCB), a Flexible Printed Circuit (FPC) board or a metal shrapnel, and assemble the antenna at the same time.

At present, products using SiP technology can be divided into two policies in the integrating solutions for antenna. The first policy is connected to the laser direct structuring (LDS) antenna through the shrapnel structure, but the first policy has the following problems: the plastic material needs to be doped with special additives; the manufacturing process is relatively complicated, such as chemical plating, resulting in potential environmental pollution issues; the shrapnel structure needs to occupy a large space, which limits the shape and the position of the antenna, and is not conducive to the miniaturization of the device; and the connection reliability of the shrapnel is low. After the shrapnel is oxidized, the resistance between the shrapnel and the metal antenna increases, causing signal attenuation. The second policy is to directly open holes on the surface of the encapsulation, fill the holes with the conductive paste, and then use vacuum printing or coating conductive paste to overlay the antenna on the SiP surface, but the second policy still has the following problems: there are requirements for the thickness of the redistribution layer, but the thicker the redistribution layer, the larger the diameter of the tapered hole; the depth of the hole is deep, and there is a problem of difficulty in chip removal during the hole-opening process; burning the device through the laser for a long time causes the problem of heat accumulation inside the SiP; and there is a problem with voids in the conductive paste filling process. In view of this, the market lacks an integrated structure and a manufacturing method that can solve the abovementioned problems, and thus this is an issue to be resolved by the related industry.

### SUMMARY

According to one aspect of the present disclosure, a structure of a chip package integrated antenna includes a substrate, at least one chip unit, at least two conductive units, an encapsulation, at least two conductive structures, and an antenna. The at least one chip unit is disposed on the substrate. The at least two conductive units are disposed on the substrate. The encapsulation is disposed on the substrate and covers the at least one chip unit and the at least two conductive units. The encapsulation has a top surface and at least two through holes, and the at least two through holes are respectively formed between the top surface and the at least two conductive units. The at least two conductive structures are respectively disposed on the at least two conductive units and located in the at least two through holes. The antenna is disposed on the top surface and connected to the at least two conductive structures. The antenna is electrically connected to the at least one chip unit through the at least two conductive structures, the at least two conductive units and the substrate in sequence.

According to another aspect of the present disclosure, a manufacturing method of a chip package integrated antenna includes a unit disposing step, an encapsulation forming step, a hole forming step, a conductive structure disposing step, and an antenna pad printing step. The unit disposing step includes disposing at least one chip unit and at least two conductive units on a substrate. The encapsulation forming step includes forming an encapsulation on the substrate to cover the at least one chip unit and the at least two conductive units. The encapsulant has a top surface, and the top surface includes at least two marked areas positioned to the at least two conductive units. The hole forming step includes performing a hole-opening process on the at least two marked areas to respectively form at least two through holes in the encapsulation, and exposing the at least two conductive units. The conductive structure disposing step includes disposing at least two conductive structures on the at least two conductive units. The at least two conductive structures are respectively located in the at least two through holes. The antenna pad printing step includes performing a pad printing process to form an antenna on the top surface, and connecting the antenna to the at least two conductive structures, so that the antenna is electrically connected to the at least one chip unit through the at least two conductive structures, the at least two conductive units and the substrate in sequence.

### BRIEF DESCRIPTION OF THE DRAWINGS

The present disclosure can be more fully understood by reading the following detailed description of the embodiment, with reference made to the accompanying drawings as follows:

FIG. 1 shows a cross-sectional view of a structure of a chip package integrated antenna according to a first example of a first embodiment of the present disclosure.

FIG. 2 shows a top view of the structure of the chip package integrated antenna according to the first example of the first embodiment of the present disclosure.

FIG. 3 shows a cross-sectional view of a structure of the chip package integrated antenna according to a second example of the first embodiment of the present disclosure.

FIG. 4 shows a flow chart of a manufacturing method of the chip package integrated antenna according to a second embodiment of the present disclosure.

FIG. 5A shows a schematic view of a unit disposing step and an encapsulation forming step of the manufacturing method of the second embodiment in FIG. 4.

FIG. 5B shows a schematic view of a hole forming step of the manufacturing method of the second embodiment in FIG. 4.

FIG. 5C shows a schematic view of a conductive structure disposing step and an antenna pad printing step of the manufacturing method of the second embodiment in FIG. 4.

### DETAILED DESCRIPTION

The embodiment will be described with the drawings. For clarity, some practical details will be described below. However, it should be noted that the present disclosure should not be limited by the practical details, that is, in some embodiment, the practical details is unnecessary. In addition, for simplifying the drawings, some conventional structures and elements will be simply illustrated, and repeated elements may be represented by the same labels.

It will be understood that when an element (or device) is referred to as be “connected” to another element, it can be directly connected to the other element, or it can be indirectly connected to the other element, that is, intervening elements may be present. In contrast, when an element is referred to as be “directly connected to” another element, there are no intervening elements present. In addition, the terms first, second, third, etc. are used herein to describe various elements or components, these elements or components should not be limited by these terms. Consequently, a first element or component discussed below could be termed a second element or component.

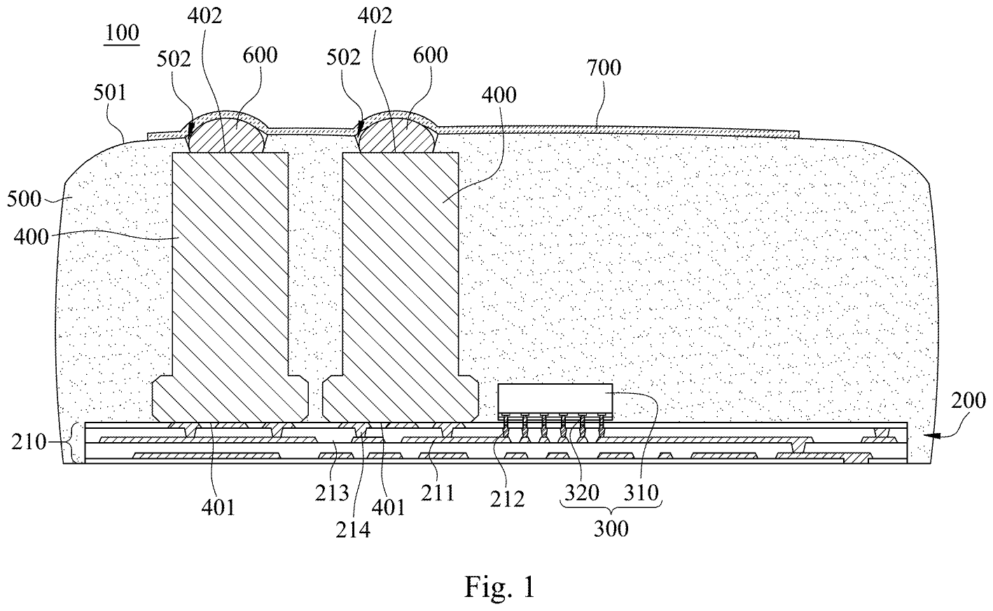

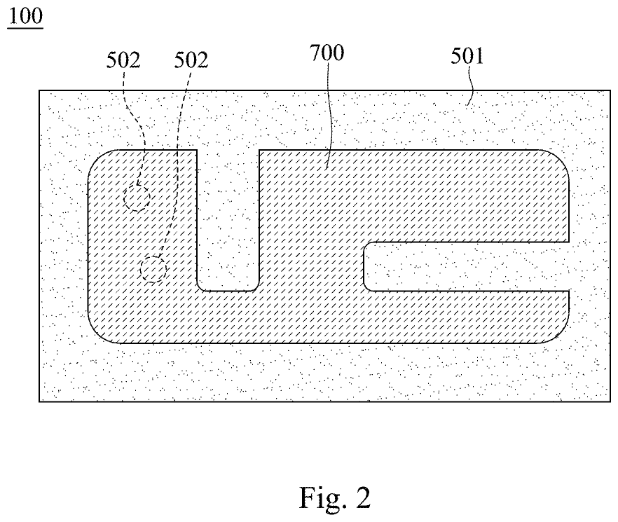

Please refer to FIGS. 1 and 2. FIG. 1 shows a cross-sectional view of a structure 100 of a chip package integrated antenna according to a first example of a first embodiment of the present disclosure. FIG. 2 shows a top view of the structure 100 of the chip package integrated antenna according to the first example of the first embodiment of the present disclosure. In FIGS. 1 and 2, the structure 100 of the chip package integrated antenna includes a substrate 200, at least one chip unit 300, at least two conductive units 400, an encapsulation 500, at least two conductive structures 600, and an antenna 700.

The substrate 200 can be a Printed Circuit Board (PCB), and includes a circuit structure 210. The circuit structure 210 includes a plurality of circuit layers 211, a top circuit layer 212, a plurality of insulating layers 213 and a plurality of via holes 214. The top circuit layer 212 is electrically connected to a part of the circuit layer 211. The via holes 214 penetrate through the insulating layer 213, so that the circuit layers 211 are electrically connected to each other. The circuit layout of the circuit structure 210 can be configured according to the needs of users, so the present disclosure is not limited thereto.

The chip unit 300 is disposed on the substrate 200 and can be bonded to the substrate 200 by the process of flip chip bonding. The chip unit 300 includes a chip 310 and a plurality of connective terminals 320 electrically connected to the chip 310. The connective terminals 320 are embedded in the circuit structure 210 and electrically connected to a plurality of circuits in the top circuit layer 212 of the circuit structure 210, so that the chip 310 can be electrically connected to the circuit structure 210 through the connective terminals 320.

The two conductive units 400 can be a pin or a metal post, and disposed on the substrate 200. Each of the conductive units 400 can include a first contact end 401 and a second contact end 402, and the first contact end 401 is electrically connected to the circuit structure 210. In addition, the two conductive units 400 can be disposed adjacent to each other on the substrate 200, but the present disclosure is not limited to the arrangement positions of the chip unit 300 and the two conductive units 400 on the substrate 200.

The encapsulation 500 is disposed on the substrate 200 and covers the chip unit 300 and the two conductive units 400. Specifically, the present disclosure utilizes an injection molding process to perform plastic package on the chip unit 300 and the two conductive units 400 to form the encapsulation 500 on the substrate 200. The encapsulation 500 has a top surface 501 and at least two through holes 502. The two through holes 502 are respectively formed between the top surface 501 and the two conductive units 400. In other words, the two through holes 502 are respectively connected between the top surface 501 of the encapsulation 500 and the two second contact ends 402 of the two conductive units 400. It should be noted that the opening method of the through hole 502 is to pre-mark a marked area on the top surface 501 that can be positioned to the conductive unit 400, and then perform a hole-opening process on the marked area to form the through hole 502.

The two conductive structures 600 are respectively disposed on the conductive units 400 and located in the two through holes 502, that is, the two conductive structures 600 are respectively electrically connected to the two second contact ends 402 of the two conductive units 400. In detail, the two conductive structures 600 are composed of conductive materials. In the first example, the conductive material forming the two conductive structures 600 can be a solder paste, and the two conductive structures 600 can be respectively disposed on the two conductive units 400 by performing a dispensing process in the two through holes 502. The dispensing process can use a pneumatic dispensing machine to send compressed air into a glue bottle (i.e., a syringe), and press the conductive material into a delivery tube connected with a piston chamber. When a piston is on the upstroke, the piston chamber is filled with the conductive material; when the piston pushes down a dispensing needle, the conductive material is pressed out from a needle nozzle of the dispensing needle. In one embodiment, the present disclosure can also use a mechanical dispenser to form the conductive structure 600 in the through hole 502 by extruding the conductive material through volumetric metering and motor driving. Two sides of the two conductive structures 600 are respectively connected to the two second contact ends 402 of the two conductive units 400, and the other two sides of the two conductive structures 600 protrude from the top surface 501 of the encapsulation 500. In other embodiments, the two conductive structures consist of a conductive material, which is a conductive silver paste. The two conductive structures are disposed on the two conductive units by performing the dispensing process in the two through holes. The conductive structure whose conductive material is the conductive silver paste has an overflow phenomenon, so that the conductive structure overflows the through hole and covers the peripheral area of the through hole.

The antenna 700 is disposed on the top surface 501 of the encapsulation 500 and connected to the two conductive structures 600. The antenna 700 is electrically connected to the chip unit 300 through the two conductive structures 600, the two conductive units 400 and the substrate 200 in sequence. The antenna 700 is composed of a conductive material; preferably, the conductive material can be the conductive silver paste. In one embodiment, the antenna 700 is formed on the top surface 501 and the two conductive structures 600 by a pad printing process. It is worth mentioning that since at least one of the two conductive structures 600 protrudes from the top surface 501, the contact area between the conductive structure 600 and the antenna 700 can be increased, thereby improving the reliability of the electrical coupling between the antenna 700 and the circuit structure 210. The shape/structure of the antenna 700 in FIG. 2 can be changed according to the user's frequency band configuration requirements, so the present disclosure is not limited thereto. Further, the numbers of the conductive units 400, the through holes 502 and the conductive structures 600 are all the same, but the present disclosure is not limited to the numbers of the chip units 300, the conductive units 400, the through holes 502 and the conductive structures 600.

Therefore, the structure 100 of the chip package integrated antenna of the present disclosure presets the conductive unit 400 on the substrate 200, uses the injection molding process to perform plastic package on the conductive unit 400, opens the through hole 502 on the marked area positioned to the conductive unit 400, and then deposes the conductive structure 600 on the conductive unit 400 through the through hole 502, and the antenna 700 is printed on the top surface 501 and the conductive structure 600 through the pad printing process finally, so that the configuration of the conductive unit 400 and the conductive structure 600 can be used to shorten the filling path of the conductive paste between the antenna and the substrate in the prior art. Moreover, since the size of the through hole 502 is much smaller than the size of the through hole between the antenna and the substrate in the prior art, it can solve the problem of long-time laser heat accumulation in the prior art.

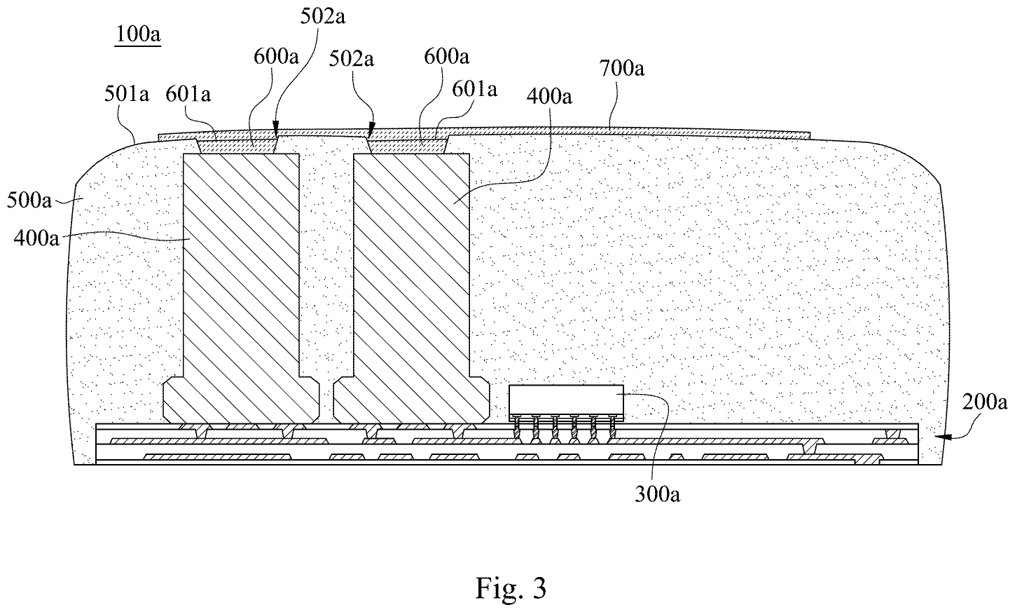

Please refer to FIG. 3. FIG. 3 shows a cross-sectional view of a structure 100a of a chip package integrated antenna according to a second example of the first embodiment of the present disclosure. In FIG. 3, the structure 100a of the chip package integrated antenna includes a substrate 200a, at least one chip unit 300a, at least two conductive units 400a, an encapsulation 500a, at least two conductive structures 600a, and an antenna 700a. The substrate 200a, the chip unit 300a, the two conductive units 400a and the encapsulation 500a of the second example are all the same as the corresponding elements of the structure 100 of the chip package integrated antenna of the first example, and are not described again herein.

In the second example, the two conductive structures 600a are composed of a conductive material, which is the conductive silver paste. Each of the conductive structures 600a has a surface 601a, and the two surfaces 601a of the two conductive structures 600a are respectively located in the two through holes 502a. In other words, one side of the conductive structure 600a is connected to the conductive unit 400a, and the other side of the conductive structure 600a (i.e., the surface 601a) is located between the conductive unit 400a and the top surface 501a. Since the antenna 700a is formed on the top surface 501a and the two conductive structures 600a by the pad printing process, the area of the antenna 700a corresponding to the conductive structure 600a has the same shape as the surface 601a of the conductive structures 600a.

A method for manufacturing the structure 100 of the chip package integrated antenna in FIG. 1 is described in more detail with the drawings below.

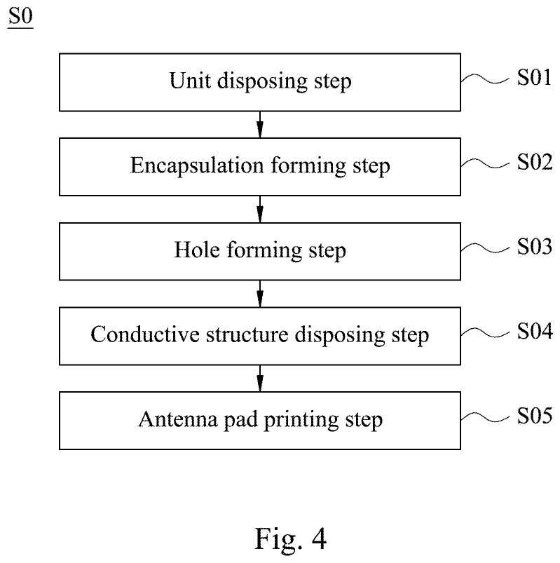

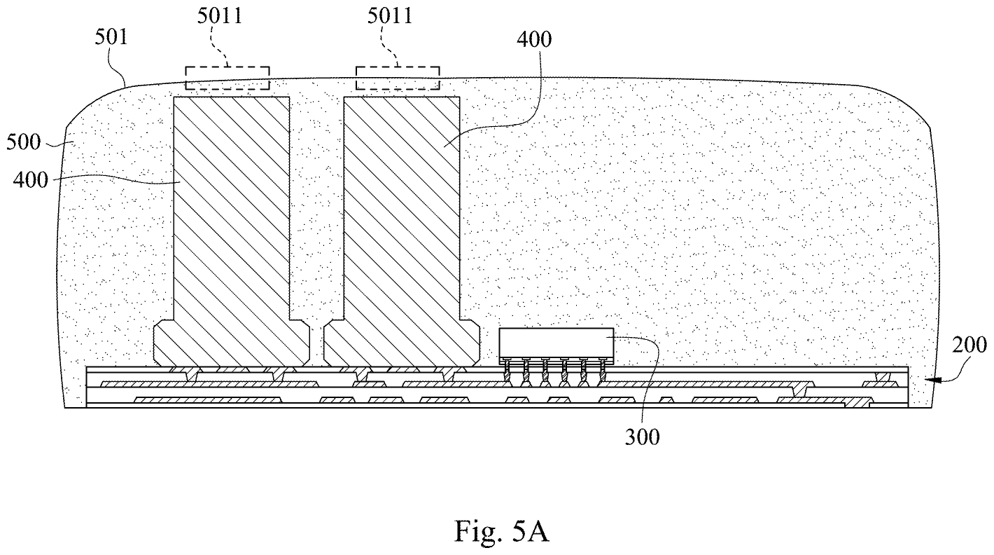

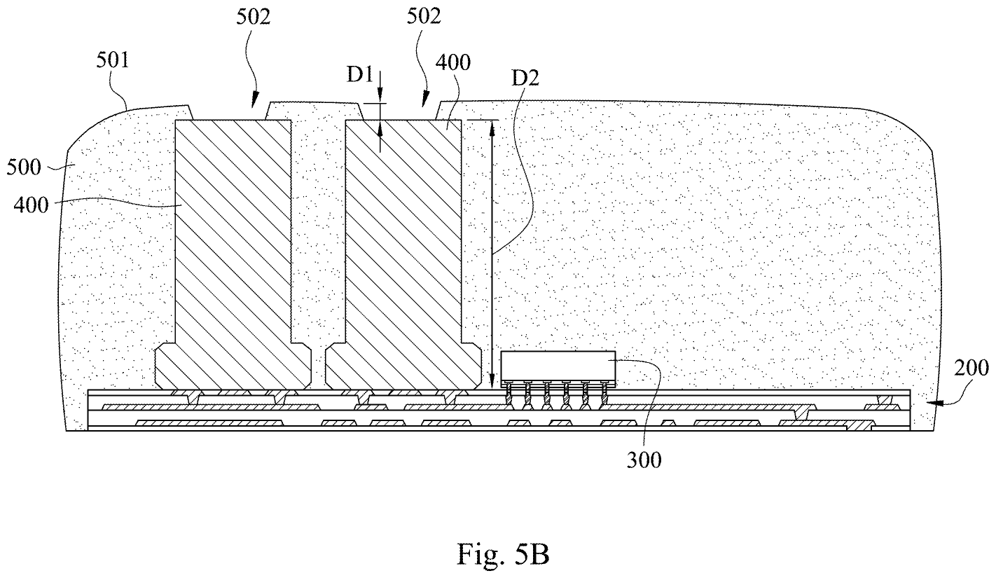

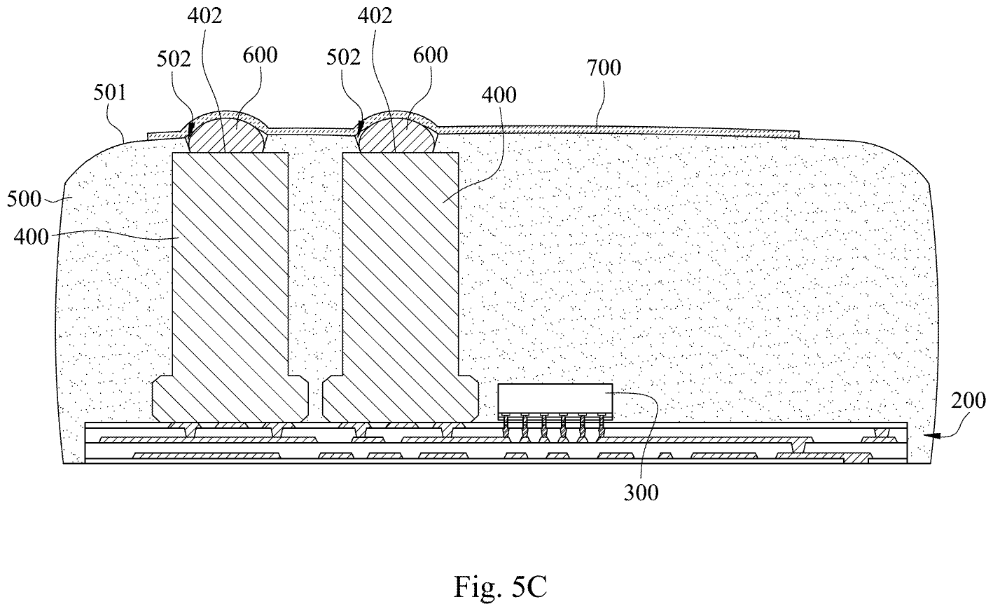

Please refer to FIGS. 4, 5A, 5B and 5C. FIG. 4 shows a flow chart of a manufacturing method S0 of a chip package integrated antenna (hereinafter referred to as the manufacturing method S0) according to a second embodiment of the present disclosure. FIG. 5A shows a schematic view of a unit disposing step S01 and an encapsulation forming step S02 of the manufacturing method S0 of the second embodiment in FIG. 4. FIG. 5B shows a schematic view of a hole forming step S03 of the manufacturing method S0 of the second embodiment in FIG. 4. FIG. 5C shows a schematic view of a conductive structure disposing step S04 and an antenna pad printing step S05 of the manufacturing method S01 of the second embodiment in FIG. 4.

In FIG. 4, the manufacturing method S0 can be configured to manufacture the structure 100 of the chip package integrated antenna in FIG. 1, and includes the unit disposing step S01, the encapsulation forming step S02, the hole forming step S03, the conductive structure disposing step S04, and the antenna pad printing step S05.

In FIGS. 4 and 5A, the unit disposing step S01 includes disposing the at least one chip unit 300 and the at least two conductive units 400 on the substrate 200. The first contact end 401 of each of the conductive units 400 is electrically connected to the substrate 200. The encapsulation forming step S02 includes using the injection molding process to perform plastic package on the chip unit 300 and the two conductive units 400 to form the encapsulation 500 on the substrate 200 to cover the chip unit 300 and the two conductive units 400. The encapsulant 500 has the top surface 501, and the top surface 501 includes at least two marked areas 5011 positioned to the at least two conductive units 400. The number of the marked areas 5011 is consistent with the number of the conductive units 400, and the marked areas 5011 is marked on the top surface 501 immediately after the injection molding process is completed.

In FIGS. 4 and 5B, the hole forming step S03 includes performing the hole-opening process on the two marked areas 5011 to respectively form the two through holes 502 in the encapsulation 500, and exposing the two conductive units 400. In detail, the hole-opening process can be a laser opening process, which focuses the laser as a high-intensity heat source to heat the encapsulation 500 under the marked area 5011, so that the encapsulation 500 under the marked area 5011 is melted or vaporized to form the through hole 502. A depth D1 of the through hole 502 is much smaller than a length D2 of the conductive unit 400, and the sum of the depth D1 and the length D2 is equal to a distance between the substrate 200 and the top surface 501 of the encapsulation 500.

In FIGS. 4 and 5C, the conductive structure disposing step S04 includes disposing the two conductive structures 600 on the two conductive units 400. The two conductive structures 600 are respectively located in the two through holes 502. In detail, the conductive structure disposing step S04 can further include performing the dispensing process to a conductive material into the two through holes 502 to form the two conductive structures 600, and at least one of the two conductive structures 600 can protrude from the top surface 501 of the encapsulation 500.

The antenna pad printing step S05 includes performing the pad printing process to form the antenna 700 on the top surface 501 of the encapsulation 500, and connecting the antenna 700 to the two conductive structures 600, so that the antenna 700 is electrically connected to the chip unit 300 through the two conductive structures 600, the two conductive units 400 and the substrate 200 in sequence. Therefore, the manufacturing method S0 of the present disclosure can integrate the antenna 700 and the chip unit 300 into the same package through the above steps, thereby realizing Antenna in Package (AiP) technology. In addition, the manufacturing method S0 of the present disclosure can also be configured to manufacture the structure 100a of the chip package integrated antenna in FIG. 3.

According to the aforementioned embodiments and examples, the advantages of the present disclosure are described as follows.

1. The oxidation problem of the metal shrapnel in the prior art can be solved so as to improve the stability of the signal connection.

2. The configuration of the conductive unit and the conductive structure can be used to shorten the filling path of the conductive paste between the antenna and the substrate in the prior art.

3. Since the required filling path (i.e., the depth of the through hole) of the present disclosure is much smaller than that in the prior art, the problem of long-time laser heat accumulation can be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A structure of a chip package integrated antenna, comprising:
a substrate;
at least one chip unit disposed on the substrate;
at least two conductive units disposed on the substrate;
an encapsulation disposed on the substrate and covering the at least one chip unit and the at least two conductive units, wherein the encapsulation has a top surface and at least two through holes, and the at least two through holes are respectively formed between the top surface and the at least two conductive units;
at least two conductive structures respectively disposed on the at least two conductive units and located in the at least two through holes; and
an antenna disposed on the top surface and connected to the at least two conductive structures, wherein the antenna is electrically connected to the at least one chip unit through the at least two conductive structures, the at least two conductive units and the substrate in sequence.

2. The structure of the chip package integrated antenna of claim 1, wherein at least one of the at least two conductive structures protrudes from the top surface of the encapsulation.

3. The structure of the chip package integrated antenna of claim 1, wherein a surface of at least one of the at least two conductive structures is located in at least one of the at least two through holes.

4. The structure of the chip package integrated antenna of claim 1, wherein the antenna is formed on the top surface by a pad printing process.

5. The structure of the chip package integrated antenna of claim 1, wherein a material of the at least two conductive structures is a conductive silver paste or a solder paste.

6. The structure of the chip package integrated antenna of claim 1, wherein the at least two conductive units are a pin or a metal post.

7. A manufacturing method of a chip package integrated antenna, comprising:
a unit disposing step comprising disposing at least one chip unit and at least two conductive units on a substrate;
an encapsulation forming step comprising forming an encapsulation on the substrate to cover the at least one chip unit and the at least two conductive units, wherein the encapsulant has a top surface, and the top surface comprises at least two marked areas positioned to the at least two conductive units;
a hole forming step comprising performing a hole-opening process on the at least two marked areas to respectively form at least two through holes in the encapsulation, and exposing the at least two conductive units;
a conductive structure disposing step comprising disposing at least two conductive structures on the at least two conductive units, wherein the at least two conductive structures are respectively located in the at least two through holes; and
an antenna pad printing step comprising performing a pad printing process to form an antenna on the top surface, and connecting the antenna to the at least two conductive structures, so that the antenna is electrically connected to the at least one chip unit through the at least two conductive structures, the at least two conductive units and the substrate in sequence.

8. The manufacturing method of the chip package integrated antenna of claim 7, wherein the conductive structure disposing step further comprising:
performing a dispensing process to respectively fill a conductive material into the at least two through holes to form the at least two conductive structures.

9. The manufacturing method of the chip package integrated antenna of claim 7, wherein at least one of the at least two conductive structures protrudes from the top surface of the encapsulation.

10. The manufacturing method of the chip package integrated antenna of claim 7, wherein a surface of at least one of the at least two conductive structures is located in at least one of the at least two through holes.
